(19) United States
(12) Patent Application Publication
(10) Pub. No.: US 2025/0390023 A1
(43) Pub. Date: Dec. 25, 2025

(54) OVERLAPPING RETICLE PLACEMENT FOR LITHOGRAPHIC FABRICATION OF A DIE

(71) Applicant: SEMICONDUCTOR COMPONENTS INDUSTRIES, LLC, Scottsdale, AZ (US)

(72) Inventor: Jon DALEY, Boise, ID (US)

(73) Assignee: SEMICONDUCTOR COMPONENTS INDUSTRIES, LLC, Scottsdale, AZ (US)

(21) Appl. No.: 18/753,608

(22) Filed: Jun. 25, 2024

(51) Int. Cl. G03F 7/00

(52) U.S. Cl. CPC G03F 7/70258; G03F 7/70433; G03F 7/70633

(57) ABSTRACT

An illustrative die may include a first region and a second region that overlap in an overlap region, as well as an array of circuit elements arranged in a grid spanning the first region and the second region. An overlap set of circuit elements may include circuit elements from the array that are disposed in the overlap region. A first subset of this overlap set may receive a lithographic deposition of a first layer as the first layer is deposited to the first region using a first reticle aligned with the first region. A second subset of the overlap set may receive the lithographic deposition of the first layer as the first layer is deposited to the second region using a second reticle aligned with the second region. Corresponding methods, reticle sets, and systems are also disclosed.

### TECHNICAL FIELD

This description relates to lithographic fabrication of semiconductor dies, and particularly semiconductor dies that feature large arrays of similar or identical circuit elements such as pixels.

### BACKGROUND

Integrated circuits (ICs) may include millions of transistors, capacitors, resistors, and/or other components fabricated on a semiconductor substrate. Certain ICs may feature large arrays of similar or identical circuit elements. As one example, an IC could include a die with an array of thousands or millions of picture elements (“pixels”) that are used to detect or present an image. Like other ICs, ICs with large arrays of circuit elements may include semiconductor dies fabricated using various lithographic processes. However, particular challenges may arise for the lithographic fabrication processes when the size of the circuit element arrays on these dies is particular large.

### SUMMARY

Unwanted artifacts may be perceptible in output produced by integrated circuits with dies that are fabricated using relatively undersized reticles that only cover a portion of the die, such that lithographic deposition of each layer must be performed in a sequence of at least two steps. For example, an image sensor fabricated in this way may produce digital images that appear to have seams (stitch lines) or a tiled look resulting from subtle discontinuities corresponding to edges of lithographic reticles or masks used in the fabrication process. Implementations described herein help to mitigate or eliminate such undesirable artifacts by using overlapping reticle placement during the lithographic fabrication of oversized dies and taking certain steps to randomize or otherwise soften or blur the edge effects in the overlap region. For example, pixels within the overlap region may be quasi-randomly associated with either a first reticle or a second reticle so that, instead of a distinct seamline, the final image would have a gradual and imperceivable transition from pixels produced using the first reticle to pixels produced using the second reticle.

In one example implementation, a die may include a first region and a second region that overlap in an overlap region, as well as an array of circuit elements arranged in a grid spanning the first region and the second region. The die may include an overlap set of circuit elements including circuit elements from the array that are disposed in the overlap region. A first subset of this overlap set may receive a lithographic deposition of a first layer as the first layer is deposited to the first region using a first reticle aligned with the first region, while a second subset of the overlap set may receive the lithographic deposition of the first layer as the first layer is deposited to the second region using a second reticle aligned with the second region.

A die fabricated in this way, such as the example die implementation described above, may include a variety of additional elements, features, characteristics, or the like.

As one example, the array of circuit elements may include an array of pixels and the die may be implemented as an image sensor die configured to produce a photographic image based on light detected by the array of pixels. In this case, the array of circuit elements may further include a plurality of access circuits corresponding to the array of pixels and configured to facilitate operation of the array of pixels during production of the photographic image.

As another example, a third subset of the overlap set may receive a lithographic deposition of a second layer as the second layer is deposited to the first region using a third reticle aligned with the first region, while a fourth subset of the overlap set may then receive the lithographic deposition of the second layer as the second layer is deposited to the second region using a fourth reticle aligned to the second region. In this case, the third subset may be different from the first subset and the second subset. The first layer may be of a first layer type selected from a group consisting of a metal layer type, a doping layer type, and a dielectric layer type, and the second layer may be of a second layer type that is also selected from this group and that is different from the first layer type.

As another example, the die may further include a third region that overlaps the second region in an additional overlap region and that is also spanned by the grid. An additional overlap set of circuit elements may include circuit elements from the array that are disposed in the additional overlap region. As such, a third subset of the additional overlap set may receive the lithographic deposition of the first layer as the first layer is deposited to the second region using the second reticle aligned with the second region, and a fourth subset of the additional overlap set may receive the lithographic deposition of the first layer as the first layer is deposited to the third region using a third reticle aligned with the third region. In some examples involving this scenario, the first region, the second region, and the third region may be arranged collinearly such that the second region is disposed between the first region and the third region. In other examples involving this scenario, the third region may be arranged non-collinearly with the first region and the second region. Accordingly, the overlap region and the additional overlap region may overlap in a hyper-overlap region that includes: 1) a first circuit element that receives the lithographic deposition of the first layer as the first layer is deposited to the first region using the first reticle aligned with the first region, 2) a second circuit element that receives the lithographic deposition of the first layer as the first layer is deposited to the second region using the second reticle aligned with the second region, and 3) a third circuit element that receives the lithographic deposition of the first layer as the first layer is deposited to the third region using the third reticle aligned with the third region.

In still other examples, the overlap region may include a plurality of rows of the grid or a plurality of columns of the grid. The overlap set of circuit elements may be divided into the first subset and the second subset in accordance with an ordered pattern. The overlap set of circuit elements may be divided into the first subset and the second subset in accordance with a randomized pattern.

In another example implementation, a method may include: 1) performing, while a first reticle is aligned with a first region of a die, a lithographic deposition of a first layer on the first region, the die being fabricated to include an array of circuit elements arranged in a grid; and 2) performing, while a second reticle is aligned with a second region of the die, the lithographic deposition of the first layer on the second region. In this implementation, the first region may overlap the second region in an overlap region in which is disposed an overlap set of circuit elements from the array. As such, the performing of the lithographic deposition of the first layer on the first region may include depositing the first layer to a first subset of the overlap set, while the performing of the lithographic deposition of the first layer on the second region may include depositing the first layer to a second subset of the overlap set.

A method for fabricating a die such as the method described above may include a variety of additional elements, features, characteristics, or the like. For instance, method steps that lead to any of the example elements, features, or characteristics described above for the die implementation may be used.

As one example, the array of circuit elements may include an array of pixels and the die may be implemented as an image sensor die configured to produce a photographic image based on light detected by the array of pixels.

As another example, the method may further include: 1) performing, while a third reticle is aligned with the first region, a lithographic deposition of a second layer on the first region; and 2) performing, while a fourth reticle is aligned with the second region, the lithographic deposition of the second layer on the second region. In this case, the performing of the lithographic deposition of the second layer on the first region may include depositing the second layer to a third subset of the overlap set, while the performing of the lithographic deposition of the second layer on the second region may include depositing the second layer to a fourth subset of the overlap set.

As another example, the method may further include performing, while a third reticle is aligned with a third region of the die that overlaps the second region in an additional overlap region in which is disposed an additional overlap set of circuit elements from the array, the lithographic deposition of the first layer on the third region. In this case, the performing of the lithographic deposition of the first layer on the second region may include depositing the first layer to a third subset of the additional overlap set, and the performing of the lithographic deposition of the first layer on the third region may include depositing the first layer to a fourth subset of the additional overlap set.

In still other examples, the overlap region may include a plurality of rows of the grid or a plurality of columns of the grid. The overlap set of circuit elements may be divided into the first subset and the second subset in accordance with a randomized pattern.

In another example implementation, a set of reticles may be configured for use in a lithographic deposition of a first layer on a die being fabricated to include an array of circuit elements arranged in a grid. The set of reticles may include, for instance: 1) a first reticle configured to be aligned with a first region of the die for the lithographic deposition of the first layer on the first region; and 2) a second reticle configured to be aligned with a second region of the die for the lithographic deposition of the first layer on the second region. In this example, the first region may overlap the second region in an overlap region in which is disposed an overlap set of circuit elements from the array. As such, the first reticle may be configured for use in the lithographic deposition of the first layer to a first subset of the overlap set, and the second reticle may be configured for use in the lithographic deposition of the first layer to a second subset of the overlap set.

A set of reticles such as the reticles described above may include a variety of additional elements, features, characteristics, or the like. For instance, the set of reticles may include features that facilitate or lead to any of the example elements, features, or characteristics described above for the die implementation.

As one example, the array of circuit elements may include an array of pixels and the die being fabricated may implement an image sensor die configured to produce a photographic image based on light detected by the array of pixels.

As another example, the overlap region may include a plurality of rows of the grid or a plurality of columns of the grid, and the overlap set of circuit elements may be divided into the first subset and the second subset in accordance with a randomized pattern.

The details of these and other implementations are set forth in the accompanying drawings and the description below. Other features will also be apparent from the following description, drawings, and claims.

### BRIEF DESCRIPTION OF THE DRAWINGS

FIG. 1 shows illustrative aspects of a die that may be lithographically fabricated using overlapping reticles in accordance with principles described herein.

FIG. 2 shows illustrative aspects of certain circuit elements of the die of FIG. 1 in accordance with principles described herein.

FIG. 3 shows illustrative aspects of how reticles may be used for lithographic deposition of a particular layer during fabrication of differently sized dies on different wafers in accordance with principles described herein.

FIG. 4 shows illustrative aspects of how a lithographic deposition of a first layer may be performed for circuit elements in different regions of a die in accordance with principles described herein.

FIG. 5 shows additional aspects of how a lithographic deposition of a first layer may be performed for circuit elements in different regions of a die in accordance with principles described herein.

FIGS. 6A-6D show illustrative ordered patterns that may be used to divide an overlap set of circuit elements into a first subset and a second subset in accordance with principles described herein.

FIG. 7A shows illustrative aspects of how a lithographic deposition of a first layer may be performed for circuit elements in a die with more than two collinear regions in accordance with principles described herein.

FIG. 7B shows illustrative aspects of how a lithographic deposition of a first layer may be performed for circuit elements in a die with non-collinear regions in accordance with principles described herein.

FIG. 8 shows illustrative aspects of how lithographic deposition of multiple layers may be performed for circuit elements in an overlap set of circuit elements in accordance with principles described herein.

FIG. 9 shows an illustrative method for overlapping reticle placement for lithographic fabrication of a die in accordance with principles described herein.

FIG. 10 shows illustrative aspects of how overlapping reticle placement for lithographic fabrication may improve image data output by dies fabricated in accordance with principles described herein.

### DETAILED DESCRIPTION

Methods for using overlapping reticle placement to lithographically fabricate a semiconductor die are described herein, as well as various example implementations of dies fabricated using such techniques.

Integrated circuit (IC) components generally include a semiconductor die (or, in some cases, a plurality of such dies) that is fabricated using lithographic processes and is packaged in a manner that the delicate die may be used for its intended purpose while being protected from environmental conditions and electrostatic events that could damage the die. Dies are generally produced in batches of several similar or identical dies on a single semiconductor wafer. For example, a wafer may host a grid of dozens or hundreds of dies that, after fabrication, may be separated from one another, tested, and individually packaged to create the IC product.

Typical lithographic processes use masks or reticles to deposit, layer by layer, intricate patterns of conductive metal material, insulative dielectric material, different types of semiconductor doping (N-type or P-type, etc.) to alter the characteristics of semiconductor material, and so forth. Each of these layers may be deposited or applied to the wafer in a process step referred to herein as a lithographic deposition of that layer. For example, certain lithographic depositions may involve depositing or growing a certain type of material such as metal or dielectric material, other lithographic depositions may involve removing or etching away such materials that have already been deposited in a previous layer, and still other lithographic depositions may involve doping the semiconductor or performing other steps.

Dedicated reticles (also referred to as masks) may be developed for each lithographic deposition in a sequence of lithographic depositions that ultimately result in a wafer of several functional dies. For example, a reticle corresponding to a first layer may be large enough to facilitate a lithographic deposition of the first layer to a several dies at a time, such as to 6 dies in a 2×3 matrix, 4 dies in a 2×2 matrix, 2 dies in a 2×1 matrix, or the like. The size of the reticle, as well as the size of the dies, may determine how many dies at once may be served by the reticle. For situations where the dies are quite large compared to the reticles, however, it may not be possible for the reticle to cover more than one die at a time. For example, if the reticle is the same size as the die, the first layer may be deposited only to one die at a time using the reticle. After deposition at the one die, the reticle may be moved to the next die to repeat the process until each die on the wafer has the lithographic deposition of the first layer.

In even more extreme cases, a die-to-reticle ratio may be such that multiple reticles are aligned to different regions of the same die for the lithographic deposition of a single layer. For example, this could be the case for reticles associated with lithographic deposition of particular layers on dies that feature large arrays of similar or identical circuit elements. As one example, an optical sensor IC may include a die with an array of tens or hundreds of millions of light detection elements (referred to as pixels) that may each be configured to transform light energy into electrical signals for high-resolution image capture. As another example, a die for a display panel may include an array of thousands or millions of light emission elements (also referred to as pixels and including elements such as light emitting diodes) that may each be configured to transform electrical signals into light for the display of images. Other dies with large arrays of circuit elements may include pixel driver dies used to provide and/or receive signaling from pixels of optical sensors or display panels, variations of pixel-related dies (such as infrared (IR) sensors, reflective sensors, fiber optic sensors, photoelectric sensors, etc.), and so forth. Such dies may also be so large as to also require multiple reticles for formation when a single reticle is too small to cover the entire die, as well as multiple steps for lithographic deposition.

Reticles or masks that are configured to facilitate a multi-step lithographic deposition of each particular layer on a die are referred to herein as “undersized reticles” with respect to the comparatively oversized dies they are being used to fabricate. Lithographic fabrication that uses an undersized reticle to lithographically deposit a portion of a large array of circuit elements (such as pixels) onto an oversized die may be especially susceptible to unwanted artifacts in output that such dies eventually produce. For example, such artifacts may result from a variety of lithography differences that tend to be essentially unavoidable across a large array of circuit elements like pixels. Small differences in critical dimension, profile, alignment, or other features of a lithographic deposition may show up in neighboring circuit elements at edges where the same reticle was moved or a different reticle was used. As a result, undesirable artifacts may tend to arise when a die is fabricated in this way, regardless of the amount of care taken or the sophistication of the equipment employed to move and align undersized reticles and oversized dies from step to step during a multi-step lithographic deposition of a particular layer.

As an example of how such artifacts may manifest when an oversized die is fabricated using undersized reticles in this way, an image sensor die with a large array of pixels is considered. Differences in critical dimension, profile, alignment, and other features could produce shifts in quantum efficiency, dark current, or other pixel parameters that would produce visible artifacts in the pixel output of immediately adjacent regions on the die. Consequently, a digital image generated using such a die may have a visible seam, stitch line, tiled effect, or other such discontinuity associated with edge of the undersized reticle. This results in a significant technical challenge for the design and fabrication of such dies, since it may be desirable for large arrays of circuit elements to be implemented on a single die, while it may be undesirable for artifacts, such as seams, to be perceivable in the resulting output (e.g., captured images, presented images, etc.) produced by such dies.

Implementations described herein provide technical solutions to technical problems associated with unwanted artifacts being perceivable in the output of dies fabricated in this way. Specifically, as detailed below, reticles used for different regions of an oversized die in the process of lithographically depositing a particular layer may be configured to overlap in their placement on the die. As a result of multiple reticles being used for overlap regions of the die, seams that may otherwise exist may be blurred or otherwise mitigated by using an ordered or randomized pattern to inconspicuously fade from one reticle region to a neighboring reticle region. In this way, as will be illustrated and further described below, unsightly seam lines that may otherwise be perceived relatively easily by a viewer of an image produced using the die may be reduced. It may therefore be much more difficult, if not impossible, for a human to perceive, even if the same unavoidable differences in critical dimension, profile, alignment, and so forth are still present.

As detailed below, the ordered or randomized selection of circuit elements near edges of reticles in overlap may be done in a variety of ways. In some cases, the selection may even be different for each different lithographic layer to further obscure and obfuscate potential artifacts that could otherwise be visible. This technical solution may be applied to various types of circuit elements including pixels, access circuits such as row and/or column drivers, and/or other types of circuit elements used for other types of applications. The technical effect of this solution is that large arrays of circuit elements may be fabricated using reticles that are too small to cover an entire die, but unavoidable pixel differences and features will not result in visible seams and/or other perceivable artifacts.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Methods for overlapping reticle placement for lithographic fabrication of a die and dies produced thereby may result in any or all of the technical benefits mentioned above, as well as various additional technical benefits that will be described and/or made apparent below.

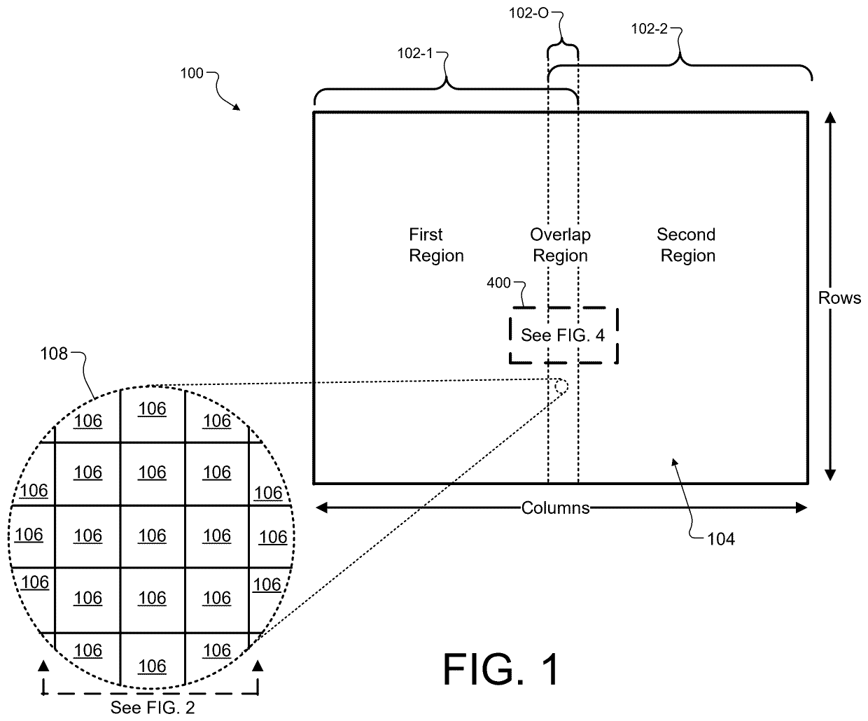

FIG. 1 shows illustrative aspects of a die that may be lithographically fabricated using overlapping reticles in accordance with principles described herein. Specifically, a die 100 is shown in FIG. 1 that will be understood to be an oversized die that includes an array of circuit elements and that is to be fabricated using undersized reticles with respect to the die size, such that the reticles are smaller than die 100 itself. As one example, the array of circuit elements may include an array of pixels and die 100 may be implemented as an image sensor die configured to produce a photographic image based on light detected by the array of pixels. In other examples, other types of circuit elements for other suitable types of dies may benefit from the same principles described in relation to this image sensor example. As one example, for instance, an array of pixels configured to emit light, rather than sense light, could be integrated on a large display panel die.

As shown, die 100 includes a first region 102-1 and a second region 102-2. Each of these regions will be understood to represent a region of die 100 that is covered by a reticle during the fabrication process, such that lithographic deposition for each layer may be performed in two steps (with two different reticles for the two regions or with a single reticle that is moved from one region to the other) for this example. Rather than abutting one another along a defined edge, regions 102-1 and 102-2 are shown to overlap in an overlap region 102-O (‘O’ for overlap).

While not explicitly visible on the die itself, it will be understood that die 100 may include an array 104 of circuit elements 106. For example, if die 100 implements an image sensor die, as per the example mentioned above, millions of identical or similar pixels (associated with different colors, etc.) included in array 104 may be arranged in a grid of horizonal rows (“Rows”) and vertical columns (“Columns”) spanning regions 102-1 and 102-2. Since regions 102-1 and 102-2 overlap, the grid of pixels will also be understood to span overlap region 102-0. For example, regions 102-1 and 102-2 may each include hundreds or thousands of columns while overlap region 102-O may include one column or a comparatively small plurality of columns, such as two columns, four columns, ten columns, etc.

These numbers of columns are provided for illustrative purposes and it will be understood that the regions of die 100 are not drawn to scale and each region 102-1, 102-2, and region 102-O, may comprise any suitable number of columns as may serve a particular implementation. Additionally, while regions 102-1, 102-2, and 102-O are shown in the example of FIG. 1 to be composed of full columns from array 104, it will be understood that, in other examples, similar regions may include full rows rather than full columns, or may include partial rows and columns so as to only cover a quadrant or other limited part of the die.

An expansion 108 of a small portion of array 104 from overlap region 102-0 is shown to include individual circuit elements 106. As mentioned, these circuit elements 106 may represent pixels of an image sensor or other suitable circuit elements that may be included in a large array for a die intended for another function. In the image sensor pixel implementation, for example, each circuit element 106 may include a photodiode and electrical components such as resistors, transistors, and capacitors configured to allow the pixel to be read out. Each of these circuit elements 106 will be understood to be identical or at least to serve similar or analogous functions as other circuit elements 106 in array 104. For instance, each circuit elements 106 may represent an identical pixel or may represent similar pixels of different colors. Another type of circuit element that may be represented by circuit elements 106 may be an access circuits corresponding to an array of pixels that is configured to facilitate operation of the array of pixels during production of a photographic image. Examples of both of these types of circuit elements will be illustrated and described below.

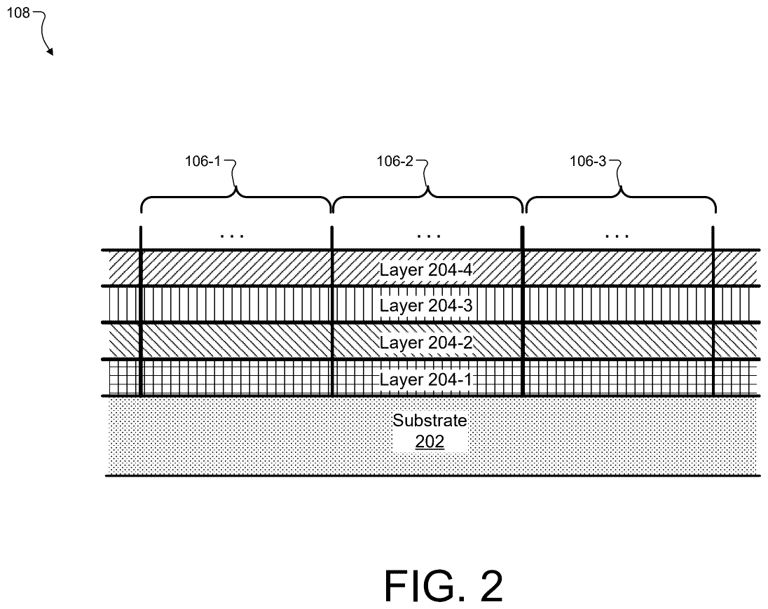

As has been mentioned, the fabrication of die 100, and of each circuit element 106 in particular, may be accomplished by way of a sequence of lithographic depositions of various layers onto a semiconductor substrate. As shown by an indicator in FIG. 1 (arrows labeled “See FIG. 2”), FIG. 2 shows a side view of a few such layers for certain circuit elements 106 of die 100 in accordance with principles described herein.

Specifically, as shown in FIG. 2, a first circuit element 106-1, a second circuit element 106-2, and a third circuit element 106-3 are each shown to be lithographically fabricated on a substrate 202 to include various layers 204-1, 204-2, 204-3, 204-4, and so forth. For example, substrate 202 may represent a silicon substrate or a substrate of another suitable semiconductor material from which a wafer (described in more detail below) is constructed and on which one or more dies such as die 100 is fabricated. Each layer 204-1 through 204-4 may then represent a particular layer applied by way of a particular lithographic deposition associated with one or more particular reticles. These layers 204-1 through 204-4 may be of various layer types. For example, one or more of these layers may be of a metal layer type and may include conductive material (e.g., aluminum, etc.) that is grown or otherwise deposited to facilitate the flow of current. One or more other layers may be of a dielectric layer type and may include insulative material (e.g., silicon dioxide, etc.) that is grown or otherwise deposited to impede the flow of current. One or more other layers may be of a doping layer type and may involve altering semiconductor material from substrate 202 or a previously applied semiconductor layer in a particular way to influence its semiconductive properties in desirable ways, such as by creating N-type or P-type semiconductor properties.

When these and other types of layers are systematically deposited onto a semiconductor wafer (substrate 202) in accordance with intricate patterns incorporated by reticles (masks) designed for this purpose, the various circuit elements 106 may be fabricated to include various electrical components such as transistors, resistors, capacitors, and so forth that are configured to perform desired functionality. Fabrication may include laying down, growing, etching, developing, applying, or otherwise depositing the various circuit elements. While a few example layer types have explicitly been mentioned, it will be understood that various other lithographic layer types (such as poly gate layers, implant layers, etc.) and/or analogous lithographic deposition steps may be performed in the course of fabricating a die with circuit elements such as circuit elements 106. In some cases, lithographic fabrication of a die may involve dozens of lithographic depositions of dozens of layers to create extremely small and complex electrical circuits.

FIG. 2 is shown to include a side view of circuit elements 106-1 through 106-3 from the expansion 108 that, in FIG. 1, is shown to be included within overlap region 102-0. As such, and as will be described in more detail below, it will be understood that different layers (such as layers 204-1 through 204-4) of different circuit elements 106 may be lithographically deposited using either a first reticle associated with region 102-1 or a second reticle associated with region 102-2. For example, all layers of all three circuit elements 106-1 through 106-3 may be lithographically deposited with reticles associated with one of regions 102-1 or 102-2, or some combination may be used. For instance, certain circuit elements 106-1 through 106-3 and/or certain layers of these circuit elements may be lithographically deposited using reticles associated with region 102-1, while the other circuit elements 106-1 through 106-3 and/or the other layers of these circuit elements may be lithographically deposited using reticles associated with region 102-2. In other words, unlike circuit elements 106 outside of an overlap region 102-0, each of these circuit elements 106-1 through 106-3 within the overlap region may be adjacent to circuit elements fabricated using different reticles.

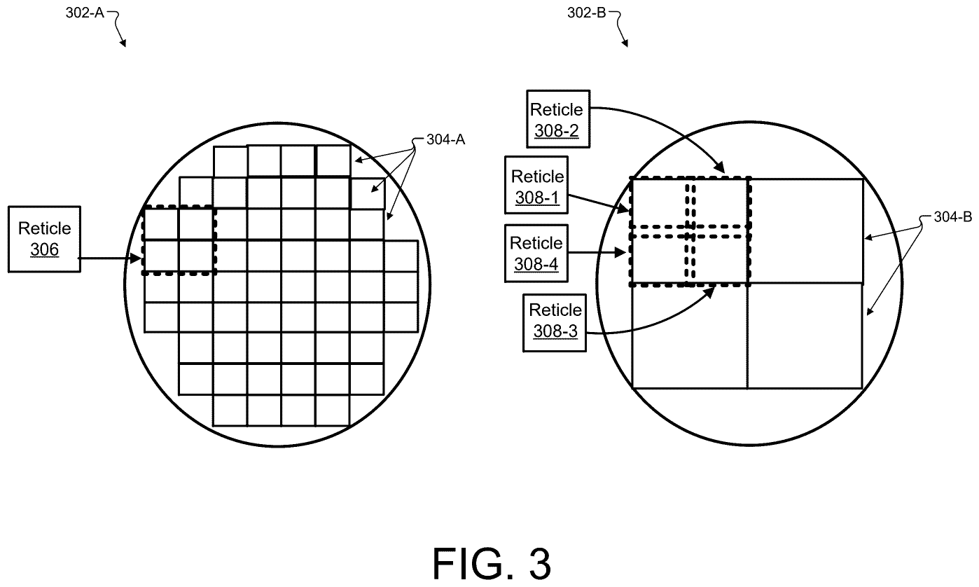

To further illustrate, FIG. 3 shows certain aspects of how reticles may be used for lithographic deposition of a particular layer during fabrication of differently sized dies on different wafers in accordance with principles described herein. Specifically, FIG. 3 shows both a wafer 302-A that includes a relatively large number of relatively small dies 304-A, as well as a wafer 302-B that includes a relatively small number of relatively large dies 304-B. Though reticles used in the lithographic fabrication process of both wafers 302-A and 302-B may be comparable in size, FIG. 3 shows that a reticle 306 used for a lithographic deposition of a particular layer on dies 304-A may fully cover the dies. In fact, as shown in this example reticle 306 may be large enough to fully cover four dies 304-A at once. Accordingly, the lithographic deposition of this particular layer may be deposited by aligning reticle 306 with up to four dies, performing the lithographic deposition for those four dies, then realigning reticle 306 to deposit the same layer on other groups of up to four dies at once until the lithographic deposition of the particular layer has been performed for all the dies 304-A.

In contrast, dies 304-B on wafer 302-B are shown to be considerably larger than dies 304-A. For example, even if wafers 302-A and 302-B are identical or similar sizes, dies 304-B may include arrays with many more circuit elements of the same size for higher pixel resolution or the like than dies 304-A. Alternatively, dies 304-B may include arrays with a similar number of larger circuit elements than dies 304-A. While reticles used in the fabrication of dies 304-B may be similar in size to reticle 306, these reticles may be undersized reticles given the larger size of dies 304-B, thereby also making dies 304-B oversized dies given the size of the reticles. As a result, FIG. 3 shows that multiple reticles 308-1, 308-2, 308-3, and 308-4 may be used to perform the lithographic deposition of a single layer onto each die 304-B. More particularly, as shown, a reticle 308-1 may be used to perform the lithographic deposition of the particular layer on a top-left quadrant of each die 304-B, a reticle 308-2 may be used to perform the lithographic deposition of the particular layer on a top-right quadrant of each die 304-B, a reticle 308-3 may be used to perform the lithographic deposition of the particular layer on a bottom-right quadrant of each die 304-B, and a reticle 308-4 may be used to perform the lithographic deposition of the particular layer on a bottom-left quadrant of each die 304-B.

The relative wafer, die, and reticle sizes shown in FIG. 3 will be understood to be non-limiting examples offered to illustrate a more standard fabrication scenario (wafer 302-A) and the more special case scenario involving oversized dies and undersized reticles (wafer 302-B). Other examples may involve other numbers or arrangements of dies on a wafer and/or other ratios of dies to a reticle. For example, while a reticle-to-die ratio of 1:4 is employed for wafer 302-A and an oversized ratio of 4:1 is employed for wafer 302-B in FIG. 3, other standard ratios (e.g., 1:9, 1:6, 1:2, 1:1, etc.) or oversized ratios (e.g., 2:1, 3:1, 6:1, 8:1, etc.) could be employed in other examples.

Additionally, it will be understood that, in certain examples, each reticle 308-1 through 308-4 could represent different reticles dedicated to the particular regions where they are used. The different reticles may have different patterns. In other examples, however, two or more of reticles 308-1 through 308-4 could represent a same reticle that is used for multiple regions of each die (being realigned to different regions in different steps of the lithographic deposition of the particular layer).

Lithographic equipment is configured to perform extremely precise alignment of reticles to regions of a wafer, such that a standard-sized reticle such as reticle 306 may be used to perform a lithographic deposition on groups of dies that are immediately adjacent to one another. Similarly, undersized reticles such as reticles 308-1 through 308-4 may be aligned such that the region covered by one reticle is immediately adjacent to the region covered by another reticle. As shown in FIG. 3, however, reticles 308-1 through 308-4 are not shown to be placed flush to one another in this way, but, rather, are shown to have overlapping placement. As such, for example, FIG. 3 shows a narrow (vertical) overlap region between where reticle 308-1 is placed and where reticle 308-2 is placed, another narrow (horizontal) overlap region between where reticle 308-2 is placed and where reticle 308-3 is placed, and so forth. There is even shown to be a small region in the center of the die 304-B where placement of all four reticles 308-1 through 308-4 overlaps. This region will be referred to herein as a hyper-overlap region, since it is where more than two reticles overlap. As has been described, these overlap regions allow for transitions between circuit elements fabricated with different reticles according to non-linear patterns including ordered patterns and randomized patterns.

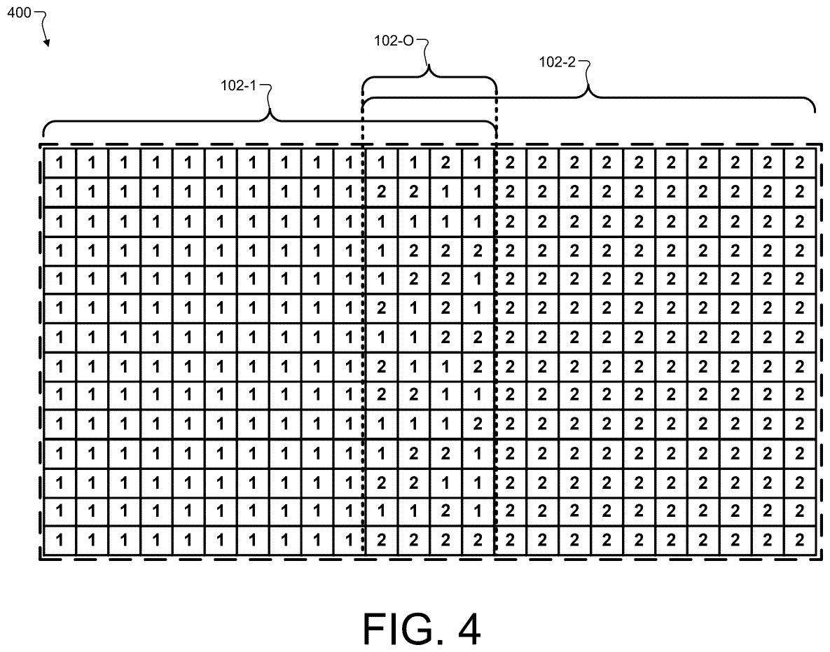

To further illustrate various aspects of how overlapping reticle placement in this way may be employed for lithographic fabrication of oversized dies FIGS. 4, 5, 6A-6D, 7A-7B, and 8 will now be described.

FIG. 4 shows illustrative aspects of how a lithographic deposition of a first layer may be performed for circuit elements (such as pixels) in different regions of a die in accordance with principles described herein. As was indicated by a box labeled “See FIG. 4” in FIG. 1, FIG. 4 shows an example expansion 400 of various circuit elements 106 from parts of array 104 spanning region 102-1, region 102-2, and overlap region 102-0. Each circuit elements 106 represented in expansion 400 is drawn as a small square with a number ‘l’ or ‘2’ that will be understood to represent whether the lithographic deposition of the first layer is performed either: 1) as the first layer is deposited to region 102-1 using a first reticle aligned with region 102-1 (boxes labeled ‘1’), or 2) as the first layer is deposited to region 102-2 using a second reticle aligned with region 102-2 (boxes labeled ‘2’).

For example, a set of circuit elements 106 that are only in region 102-1 (i.e., those circuit elements 106 that are in region 102-1 but outside of 102-0) are all labeled ‘1’ to indicate that these are deposited to region 102-1 using the first reticle when it is aligned with region 102-1. Similarly, a set of circuit elements 106 that are only in region 102-2 (i.e., those circuit elements 106 that are in region 102-2 but outside of 102-0) are all labeled ‘2’ to indicate that these are deposited to region 102-2 using the second reticle when it is aligned with region 102-2. Additionally, a set of circuit elements 106 that are in both regions 102-1 and 102-2, or, in other words, the set of circuit elements from array 104 that are disposed in overlap region 102-O, are labeled with either ‘1’ or ‘2’ in accordance with, in this example, a randomized pattern. This set of circuit elements 106 is referred to herein as an overlap set of circuit elements.

As shown, the overlap set of circuit elements 106 within the columns included in overlap region 102-O include: 1) a first subset of circuit elements 106 that are each labeled ‘1’ and receive a lithographic deposition of the first layer as the first layer is deposited to region 102-1 using a first reticle aligned with region 102-1, and 2) a second subset of circuit elements 106 that are each labeled ‘2’ and receive the lithographic deposition of the first layer as the first layer is deposited to region 102-2 using a second reticle aligned with region 102-2. As shown, the second subset of circuit elements 106 (labeled ‘2’) complements the first subset (labeled ‘1’) within the overlap set. As used herein, one subset complements another subset within a set when, collectively, the two subsets include every member of the set. Thus, since every circuit element 106 in overlap region 102-O is either part of the first subset (labeled ‘1’) or the second subset (labeled ‘2’), these subsets are complementary subsets within the overlap set of circuit elements 106 included in overlap region 102-O. It is also noted that, at least for this first layer, the first subset and the second subset are disjoint subsets within the overlap set. That is, no member of the subset (i.e., no circuit element 106) is in both the first subset and the second subset. Rather, the first layer is deposited for every circuit element 106 in the overlap set either by the first reticle or the second reticle, but not by both.

As will be described in more detail below, the division of the overlap set into this first and second subset need not necessarily apply to the lithographic deposition of all the layers (though it may). Rather, the first and second subsets, as labeled in FIG. 4, will be understood to relate to a first layer in particular, and the subsets may remain the same or change for the lithographic deposition of other layers such as a second layer that is deposited using a third reticle aligned with region 102-1 and a fourth reticle aligned with region 102-2.

As has been described, a technical effect of implementing overlap region 102-O and randomizing or otherwise strategically patterning which reticles are used to lithographically deposit a particular layer to each circuit element is that the transition from one region to another may be considerably softened so as to reduce or eliminate any visual artifacts that could otherwise be produced. For example, as shown in FIG. 4, there is no column of all circuit elements 106 labeled ‘1’ that is adjacent to a column of circuit elements 106 labeled ‘2’, which is the type of scenario that could lead to an undesirable artifact. Rather, the transition between the circuit elements 106 labeled ‘1’ and the circuit elements 106 labeled ‘2’ is shown to be randomized (e.g., truly random, quasi-random, etc.) and gradual. While the human eye can detect subtle changes when a linear artifact is present, a blurred or non-linear transition resulting from this randomized pattern may result in a reduced artifact that will be much more difficult or impossible for a human to perceive. Alternatively, the randomized pattern may be a suitable ordered pattern that achieves a similar blurred or non-linear transition.

In the example of expansion 400, the circuit elements 106 may each represent a pixel from an array of pixels fabricated on die 100. However, as has been mentioned, it will be understood that array 104 of circuit elements 106 may further include other types of circuit elements. For instance, the array could include a plurality of access circuits that correspond to the array of pixels and that are configured to facilitate operation of the array of pixels during production of a photographic image.

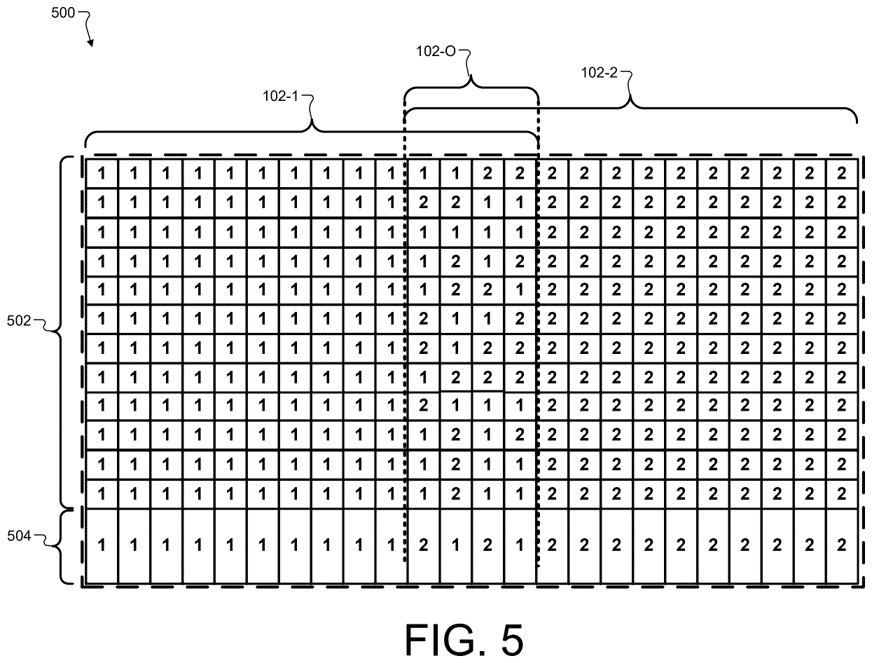

To illustrate, FIG. 5 shows additional aspects of how the lithographic deposition of the first layer may be performed for circuit elements in different regions of die 100 in a different expansion 500. As shown, expansion 500 includes both: 1) various rows 502 of circuit elements 106 implemented as pixels from an array of pixels, and 2) a row 504 of circuit elements 106 implemented as access circuits corresponding to the array of pixels in rows 502. In other implementations, other rows not shown inFIG. 5 may also be included in the same region. These access circuits may facilitate operation of the array of pixels during production of a photographic image in any suitable manner. For example, the access circuits for an image sensor example may include readout circuitry for the pixels such as row or column readout circuits, column amplifiers, or the like. Since such access circuits may also influence or contribute to the final output of die 100, FIG. 5 shows that access circuits within overlap region 102-O are similarly randomized or interleaved on row 504 to make the transition more gradual from access circuits associated with the first reticle (labeled ‘1’) and access circuits associated with the second reticle (labeled ‘2’).

The overlap set of circuit elements 106 in both expansion 400 of FIG. 4 and expansion 500 of FIG. 5 is shown to be divided into the first subset (labeled ‘1’) and the second subset (labeled ‘2’) in accordance with a randomized pattern. For instance, this pattern may be manually developed by a designer to be quasi-random or may be created using a random or quasi-random number generator. Randomized patterns such as illustrated in FIGS. 4 and 5 are not, however, the only way to accomplish the artifact reduction objective that has been described. In other examples, various types of fixed, engineered patterns may similarly be used to divide the overlap set into complementary and disjoint subsets that similarly minimize the visual impact of potential artifacts. These patterns are referred to as ordered patterns since they do not have the same random or quasi-random quality shown in the randomized patterns of expansions 400 and 500.

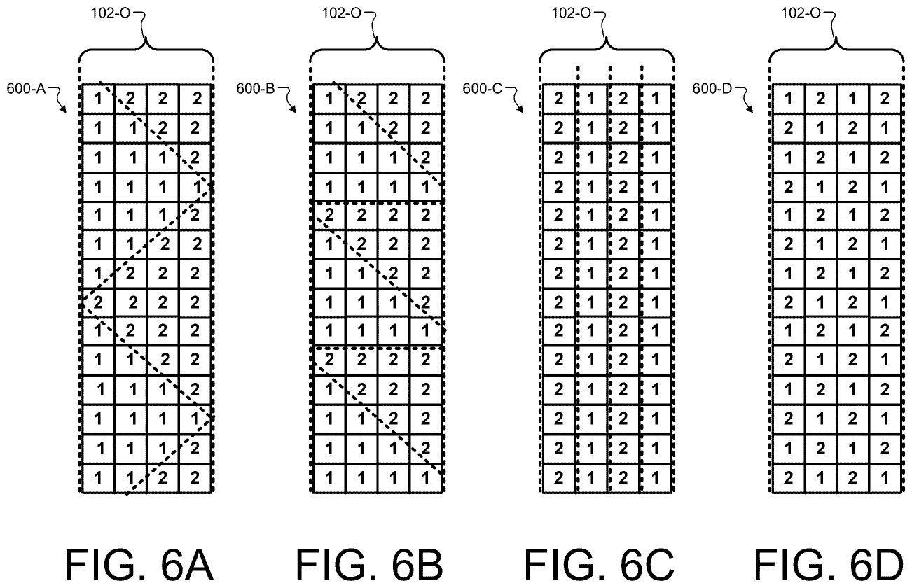

To illustrate how the overlap set of circuit elements may be divided into a first subset and a second subset in accordance with an ordered pattern, FIGS. 6A-6D show various example ordered patterns that may be used in accordance with principles described herein. Specifically, FIG. 6A shows an ordered pattern 600-A that divides the overlap set in a zigzag shape, FIG. 6B shows an ordered pattern 600-B that divides the overlap set in a sawtooth shape, FIG. 6C shows an ordered pattern 600-C that divides the overlap set in a vertically striped manner, and FIG. 6D shows an ordered pattern 600-D that divides the overlap set in a checkered manner. Dotted lines are drawn in some of these examples as visual aids to demarcate the transition from circuit elements of the first subset (labeled ‘1’) to circuit elements of the second subset (labeled ‘2’).

It will be understood that ordered patterns 600-A through 600-D are shown by way of illustration only and that various other ordered patterns may also be implemented as may serve a particular implementation. Additionally, while each of these ordered patterns and the randomized patterns of expansions 400 and 500 span an overlap region 102-O of four columns of circuit elements, it will be understood that an overlap region may include any suitable number of rows or columns as may serve a particular implementation. For example, as few as one column or row of overlap may be used in certain examples, while a plurality of two, four, ten, twenty, or another suitable number of columns or rows of overlap can be used in other examples. One tradeoff to consider in determining how many rows or columns of overlap are to be incorporated into the reticles is that a larger overlapping region may help more fully reduce any perception of an artifact, while a smaller overlapping regions with fewer columns or rows than the larger overlapping region may reduce the number of reticle placements needed to cover an entire array, thereby reducing cost and complexity of both die fabrication and reticle design.

Many examples focused on up to this point have involved just two main reticle regions (i.e., regions covered by a single reticle) with one overlap region shared between them. For example, the implementation of die 100 shown in FIG. 1 includes regions 102-1 and 102-2, which may involve two reticles with overlapping reticle placement to perform each lithographic deposition. Likewise, the examples illustrated by expansions 400 and 500, as well as the patterns for the overlapping sets of circuit elements in FIGS. 6A-6D, have similarly shown portions of two reticle regions 102-1 and 102-2 and a single overlap region. While such implementations may be useful in many real-world cases and provide descriptive and illustrate clarity and simplicity for ease of understanding, it will be understood that certain implementations may extend principles of overlapping reticle placement in various ways that will now be described.

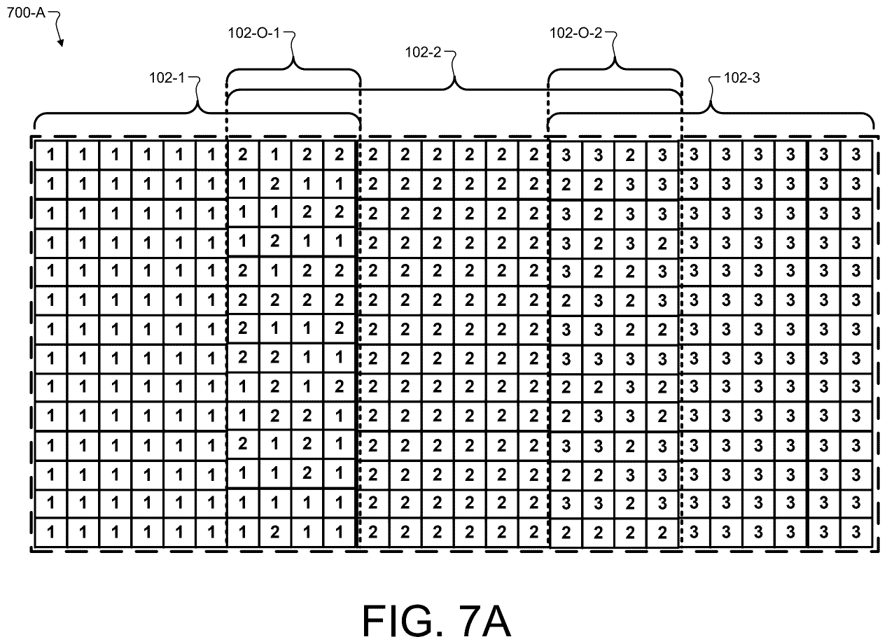

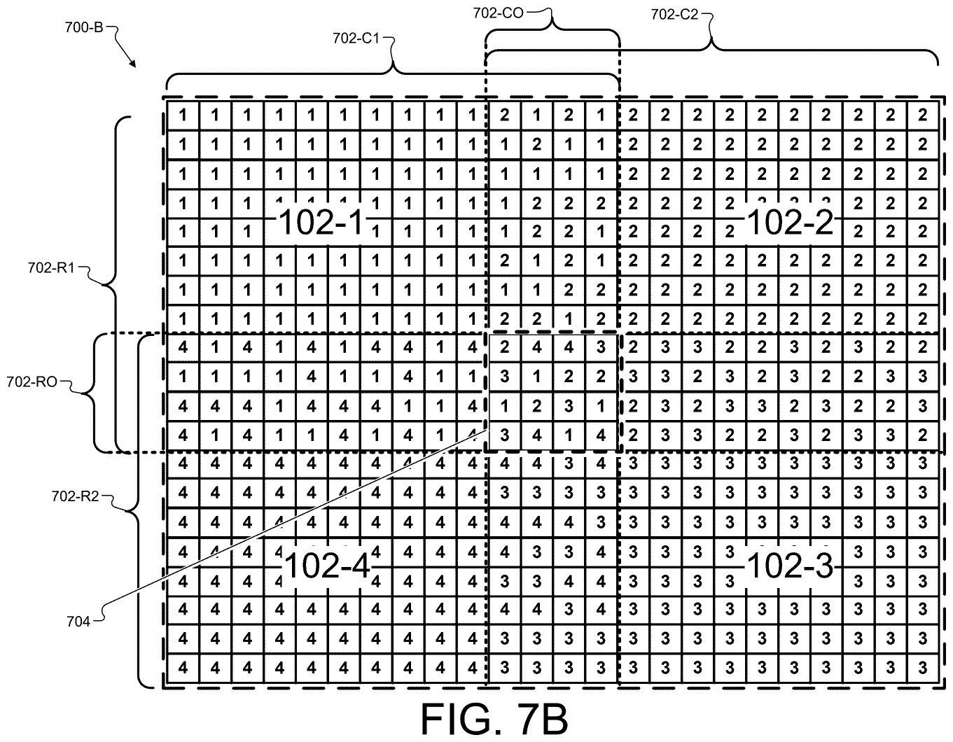

As a first example, FIG. 7A shows illustrative aspects of how a lithographic deposition of a first layer may be performed for circuit elements 106 in an implementation of die 100 with more than two collinear regions. Specifically, as shown, FIG. 7A depicts an expansion 700-A of an array that includes three collinear regions 102-1, 102-2, and 102-3. As used herein, regions are collinear when the regions all include groupings of full rows or full columns. Accordingly, the regions 102-1, 102-2, and 102-3 in FIG. 7A are collinear since they all include full columns and go in a one-dimensional, linear pattern from region 102-1 on the left to region 102-2 in the middle to region 102-3 on the right.

Just as regions 102-1 and 102-2 have included an overlap region 102-O in other examples illustrated above, the implementation of regions 102-1 and 102-2 in FIG. 7A are shown to include an overlap region 102-O-1 that includes an overlap set of circuit elements 106 that, in this example, are shown to be divided into subsets labeled ‘1’ and ‘2’ in a randomized way (as described above). Additionally, FIG. 7A shows that the third region 102-3, which is also spanned by the same grid of the circuit element array, may overlap the second region 102-2 in an additional overlap region 102-O-2. As such, an additional overlap set of circuit elements may include those circuit elements 106 that are disposed in the additional overlap region 102-O-2. Just as the overlap set within overlap region 102-O-1 are divided into a randomized first subset (labeled with ‘1’s) and a complementary second subset (labeled with ‘2’s), this additional overlap set within overlap region 102-O-2 may be divided into a third subset and a fourth subset that complements the third subset within the additional overlap set. Specifically, as shown, the third subset may be labeled with ‘2’s and the fourth subset may be labeled with ‘3’s. This is because, in this example, the third subset of the additional overlap set receives the lithographic deposition of the first layer as the first layer is deposited to the second region 102-2 using the second reticle aligned with the second region 102-2, while the fourth subset of the additional overlap set receives the lithographic deposition of the first layer as the first layer is deposited to the third region 102-3 using a third reticle aligned with the third region 102-3.

As a second example of how overlapping reticle placement principles may be extended, FIG. 7B shows illustrative aspects of how a lithographic deposition of a first layer may be performed for circuit elements 106 in an implementation of die 100 with non-collinear (or two-dimensional) regions in accordance with principles described herein. Specifically, in contrast to FIG. 7A that has first region 102-1, second region 102-2, and third region 102-3 arranged collinearly, FIG. 7B depicts an expansion 700-B of a circuit element array that includes four non-collinear regions. Specifically, regions 102-1, 102-2, 102-3, and 102-4 are shown to be associated with quadrants of the array in this example.

Similar to other examples above, each of these regions is shown to include circuit elements 106 labeled according to the region with ‘1’s, ‘2’, ‘3’s, or ‘4’s for the respective regions 102-1, 102-2, 102-3, and 102-4. As used herein, regions are non-collinear when the regions do not include groupings of full rows or full columns. Accordingly, the regions 102-1, 102-2, 102-3, and 102-4 in FIG. 7B are non-collinear since they are quadrants that include only partial rows and columns, similar to the example illustrated by die 304-B in FIG. 3. While these regions are not labeled with brackets in the same way as collinear regions above, it will be understood that region 102-1 includes the quadrant where columns 702-C1 intersect with rows 702-R1, region 102-2 includes the quadrant where columns 702-C2 intersect with rows 702-R1, region 102-3 includes the quadrant where columns 702-C2 intersect with rows 702-R2, and region 102-4 includes the quadrant where columns 702-C1 intersect with rows 702-R2. The quadrants may also easily be seen by the digits 1-4 outside of the overlap regions.

Just as regions 102-1 and 102-2 have included an overlap region 102-0 in other examples illustrated above, various overlap regions similarly are shown in FIG. 7B. Specifically, an overlap region between regions 102-1 and 102-2 (populated with randomized circuit elements labeled ‘1’ or ‘2’) exists where columns 702-CO intersect with rows 702-R1, an overlap region between regions 102-2 and 102-3 (populated with randomized circuit elements labeled ‘2’ or ‘3’) exists where columns 702-C2 intersect with rows 702-RO, an overlap region between regions 102-3 and 102-4 (populated with randomized circuit elements labeled ‘3’ or ‘4’) exists where columns 702-CO intersect with rows 702-R2, and an overlap region between regions 102-4 and 102-1 (populated with randomized circuit elements labeled ‘4’ or ‘1’) exists where columns 702-C1 intersect with rows 702-RO. Additionally, all these overlap regions are shown to overlap in a hyper-overlap region 704 that is populated with randomized circuit elements labeled ‘1’, ‘2’, ‘3’, and ‘4’. As with other examples described above, each of these overlap regions includes overlap sets that are shown to be quasi-randomly divided into two complementary subsets that are labeled with the numbers shown. Additionally, hyper-overlap region 704 is shown to include four complementary subsets associated with the four reticles used to perform the lithographic deposition of the first layer in the four regions 102-1 through 102-4.

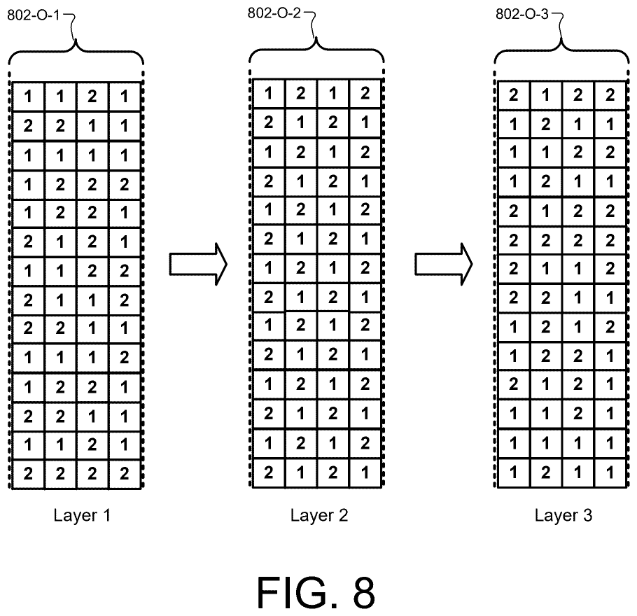

As another example of how overlapping reticle placement principles may be extended, FIG. 8 shows illustrative aspects of how lithographic deposition of multiple layers may be performed for circuit elements in an overlap set of circuit elements in accordance with principles described herein. In this example, a third subset of the overlap set of circuit elements associated with overlap region 102-O may complement a fourth subset of the overlap set within the overlap set, where: 1) the third subset receives a lithographic deposition of a second layer as the second layer is deposited to the first region using a third reticle aligned with the first region; and 2) the fourth subset receives the lithographic deposition of the second layer as the second layer is deposited to the second region using a fourth reticle aligned to the second region.

To illustrate, three versions of overlap region 102-O are shown in FIG. 8, each one representing the same circuit elements 106 but associated with a different example layer (“Layer 1,” “Layer 2,” and “Layer 3”). Specifically, an overlap region 802-O-1 will be understood to represent the overlap region 102-O for a first layer (“Layer 1”), an overlap region 802-O-2 will be understood to represent the overlap region 102-O for a second layer (“Layer 2”), and an overlap region 802-O-3 will be understood to represent the overlap region 102-O for a third layer (“Layer 3”). The overlap set of circuit elements 106 is shown for each of overlap region 802-O-1, 802-O-2, and 802-O-3. However, the complementary subsets into which the circuit elements are divided for each layer are shown to be differently randomized in each case. For example, if a first subset is shown by ‘1’s in overlap region 802-O-1 and a second subset is shown by ‘2’s in overlap region 802-O-1, a third subset shown by ‘1’s in overlap region 802-O-2 may be different from the first subset and the second subset. Similarly, a fourth subset shown by ‘2’s in overlap region 802-O-2, which complements the third subset, is therefore also different from the first subset and the second subset. Complementary fifth and sixth subsets of the overlap set shown, respectively, by ‘1’s and ‘2’s in overlap region 802-O-3 are also shown to be randomized and different from all the other subsets. It will be understood that while randomized subsets are used for each layer in the example of FIG. 8, different ordered subsets or a combination of ordered and randomized subsets could also be used. Additionally, as mentioned above, each of these layers may be of different layer types. Such different layers may include a metal layer type, a doping layer type, a dielectric layer type, and/or other suitable layer types.

Implementations described above have depicted dies that are lithographically fabricated using overlapping reticle placement in accordance with principles described herein. Other types of implementations of the above-described principles may include sets of different reticles used to fabricate such dies, methods and procedures for overlapping the placement of the reticles to fabricate such dies, and so forth.

As one additional implementation, for instance, a set of reticles may be configured for use in a lithographic deposition of a first layer on a die being fabricated to include an array of circuit elements arranged in a grid. The set of reticles may include various reticles that have been described herein, such as reticles 308-1 through 308-4. More particularly, the set of reticles may include at least: 1) a first reticle configured to be aligned with a first region of the die for the lithographic deposition of the first layer on the first region; and 2) a second reticle configured to be aligned with a second region of the die for the lithographic deposition of the first layer on the second region. In this example, the first region may overlap the second region in an overlap region in which is disposed an overlap set of circuit elements from the array. As such, the first reticle may be configured for use in the lithographic deposition of the first layer to a first subset of the overlap set and the second reticle may be configured for use in the lithographic deposition of the first layer to a second subset of the overlap set, where the second subset complements the first subset within the overlap set.

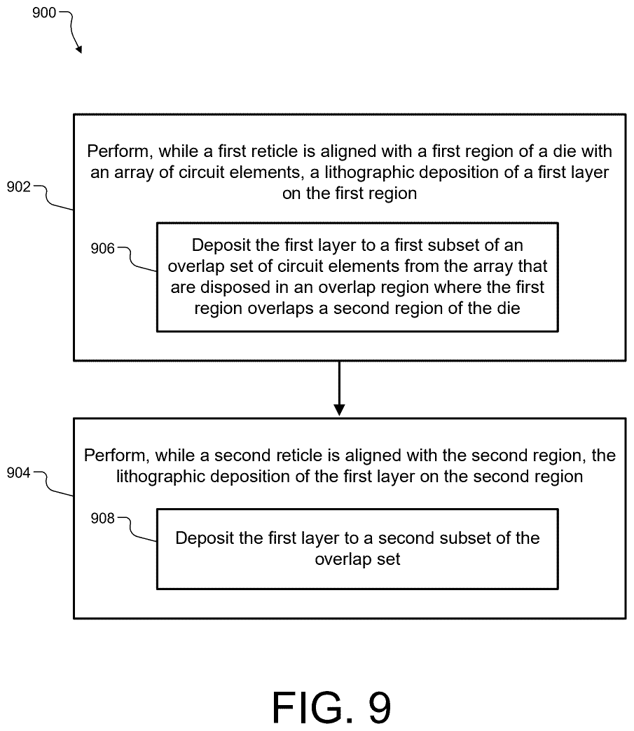

As another additional implementation, FIG. 9 shows an illustrative method 900 for overlapping reticle placement for lithographic fabrication of a die in accordance with principles described herein. While FIG. 9 shows illustrative operations 902-904 and suboperations 906-908 according to one implementation, other implementations of method 900 may omit, add to, reorder, and/or modify any of the operations and/or suboperations shown in FIG. 9. In some examples, multiple operations shown in FIG. 9 or described in relation to FIG. 9 may be performed concurrently (e.g., in parallel) with one another, rather than being performed sequentially as illustrated and/or described. Each of operations 902-904 and suboperations 906-908 will now be described in more detail as they may be performed by a lithographic fabrication system using a set of reticles such as described above.

At operation 902, a lithographic fabrication system may perform a lithographic deposition of a first layer on a first region of a die being fabricated to include an array of circuit elements arranged in a grid. For example, operation 902 may be performed while a first reticle is aligned with the first region of the die. As has been illustrated and described, this first region may overlap a second region of the die in an overlap region in which is disposed an overlap set of circuit elements from the array.

Operation 906 is shown to be included as a suboperation of operation 902. Specifically, the performing of the lithographic deposition of the first layer on the first region at operation 902 may include depositing the first layer to a first subset of the overlap set of circuit elements. As has been illustrated and described, this first subset may be a randomized subset of the overlap set or an ordered subset specifically designed to mitigate seamlines that might otherwise be perceivable in output data produced by the die.

Similarly, at operation 908, the lithographic fabrication system may perform the lithographic deposition of the first layer on the second region of the die while a second reticle is aligned with the second region of the die. As mentioned above, the second region may overlap the first region in the overlap region, such that the placement of the second reticle overlaps with the placement of the first reticle as the respective reticles are each aligned to their respective regions.

Operation 908 is shown to be included as a suboperation of operation 904. Specifically, the performing of the lithographic deposition of the first layer on the second region at operation 904 may include depositing the first layer to a second subset of the overlap set. As has been illustrated and described, this second subset may complement the first subset within the overlap set. Accordingly, just as the first subset may be a randomized or ordered subset configured to mitigate seamlines or other artifacts, the complementary subset may also have these same properties to serve the same objective.

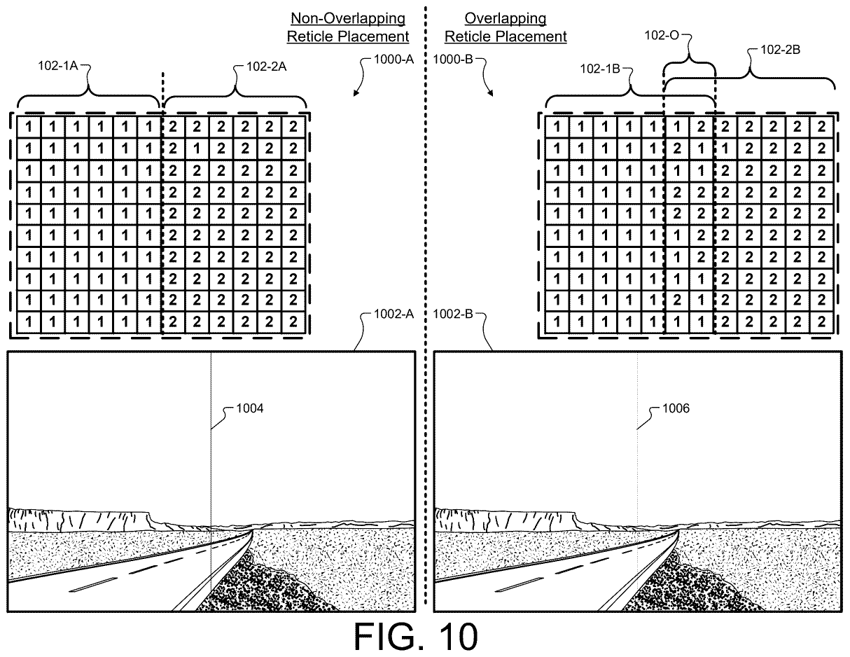

FIG. 10 shows illustrative aspects of how overlapping reticle placement for lithographic fabrication in any of the implementations described above may ultimately improve output data produced by dies fabricated in accordance with principles described herein. In particular, assuming that a die fabricated using overlapping reticle placement principles described herein is implemented as an image sensor die configured to produce a photographic image based on light detected by an array of pixels, FIG. 10 contrasts a scenario 1000-A in which an image 1002-A is output by a die fabricated with non-overlapping reticle placement and with a scenario 1000-B in which an image 1002-B is output by a die fabricated with overlapping reticle placement in accordance with principles described herein.

As shown in scenario 1000-A, a first region 102-1A and a second region 102-2A of a pixel expansion are immediately adjacent to one another but do not overlap. As a result, each pixel or other circuit element within first region 102-1A is shown to receive the lithographic deposition of a first layer using a first reticle (represented by ‘1’s) while each pixel or other circuit element within first region 102-2A is shown to receive the lithographic deposition of the first layer using a second reticle (represented by ‘2’s) with no overlap region that randomizes or otherwise mixes these. As shown, an artifact 1004 (e.g., a seamline) may be visible in image 1002-A where the pixels immediately switch from those fabricated using the first reticle to those fabricated using the second reticle. It will be understood that artifact 1004 is emphasized for purposes of illustration and may not be so conspicuous in certain implementations. However, even if the seamline is subtle, it may at least be perceivable by a viewer of the image, which would be undesirable.

As shown in scenario 1000-B, in contrast, a first region 102-1B and a second region 102-2B of a pixel expansion are shown to overlap one another in an overlap region 102-O. As a result, each pixel or other circuit element within first region 102-1B is shown to receive the lithographic deposition of a first layer using a first reticle (represented by ‘1’s), each pixel or other circuit element within first region 102-2B is shown to receive the lithographic deposition of the first layer using a second reticle (represented by ‘2’s), and an overlap set of pixels within overlap region 102-O is shown to include a randomized mix of pixels associated with both of these reticles. As a result, an artifact 1006 in image 1002-B is shown to be far less conspicuous or perceivable than artifact 1004 in image 1002-A. As has been described, the overlap region blurs or smooths out this artifact to make it harder to perceive. Just as artifact 1004 was emphasized for purposes of illustration, it will be understood that the same is true for artifact 1006. For example, while artifact 1004 may represent a very subtle artifact that is difficult to see but perceivable, artifact 1006 may represent an artifact that is so subtle as to be completely imperceivable or at least very unlikely to be noticed if a viewer is not specifically looking for it. This is an improvement over image 1002-A since 1002-B obscures the undesirable artifact while still supporting the high resolution and other advantages gained by using an oversized die fabricated in multiple steps for each layer.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. A die comprising:
a first region and a second region that overlap in an overlap region;
an array of circuit elements arranged in a grid spanning the first region and the second region; and
an overlap set of circuit elements including circuit elements from the array that are disposed in the overlap region, wherein:
a first subset of the overlap set receives a lithographic deposition of a first layer as the first layer is deposited to the first region using a first reticle aligned with the first region, and
a second subset of the overlap set receives the lithographic deposition of the first layer as the first layer is deposited to the second region using a second reticle aligned with the second region.

2. The die of claim 1, wherein the array of circuit elements includes an array of pixels and the die is implemented as an image sensor die configured to produce a photographic image based on light detected by the array of pixels.

3. The die of claim 2, wherein the array of circuit elements further includes a plurality of access circuits corresponding to the array of pixels and configured to facilitate operation of the array of pixels during production of the photographic image.

4. The die of claim 1, wherein:
a third subset of the overlap set receives a lithographic deposition of a second layer as the second layer is deposited to the first region using a third reticle aligned with the first region; and
a fourth subset of the overlap set within the overlap set receives the lithographic deposition of the second layer as the second layer is deposited to the second region using a fourth reticle aligned to the second region.

5. The die of claim 4, wherein:
the third subset is different from the first subset and the second subset;
the first layer is of a first layer type selected from a group consisting of a metal layer type, a doping layer type, and a dielectric layer type; and
the second layer is of a second layer type selected from the group and different from the first layer type.

6. The die of claim 1, wherein the die further comprises:
a third region that overlaps the second region in an additional overlap region and that is also spanned by the grid; and
an additional overlap set of circuit elements including circuit elements from the array that are disposed in the additional overlap region, wherein:
a third subset of the additional overlap set receives the lithographic deposition of the first layer as the first layer is deposited to the second region using the second reticle aligned with the second region, and
a fourth subset of the additional overlap set receives the lithographic deposition of the first layer as the first layer is deposited to the third region using a third reticle aligned with the third region.

7. The die of claim 6, wherein the first region, the second region, and the third region are arranged collinearly such that the second region is disposed between the first region and the third region.

8. The die of claim 6, wherein:
the third region is arranged non-collinearly with the first region and the second region; and
the overlap region and the additional overlap region overlap in a hyper-overlap region that includes:
a first circuit element that receives the lithographic deposition of the first layer as the first layer is deposited to the first region using the first reticle aligned with the first region,
a second circuit element that receives the lithographic deposition of the first layer as the first layer is deposited to the second region using the second reticle aligned with the second region, and
a third circuit element that receives the lithographic deposition of the first layer as the first layer is deposited to the third region using the third reticle aligned with the third region.

9. The die of claim 1, wherein the overlap region includes a plurality of rows of the grid or a plurality of columns of the grid.

10. The die of claim 1, wherein the overlap set of circuit elements is divided into the first subset and the second subset in accordance with an ordered pattern.

11. The die of claim 1, wherein the overlap set of circuit elements is divided into the first subset and the second subset in accordance with a randomized pattern.

12. A method comprising:
performing, while a first reticle is aligned with a first region of a die, a lithographic deposition of a first layer on the first region, the die being fabricated to include an array of circuit elements arranged in a grid; and
performing, while a second reticle is aligned with a second region of the die, the lithographic deposition of the first layer on the second region;
wherein:
the first region overlaps the second region in an overlap region in which is disposed an overlap set of circuit elements from the array,
the performing of the lithographic deposition of the first layer on the first region includes depositing the first layer to a first subset of the overlap set, and
the performing of the lithographic deposition of the first layer on the second region includes depositing the first layer to a second subset of the overlap set.

13. The method of claim 12, wherein the array of circuit elements includes an array of pixels and the die is implemented as an image sensor die configured to produce a photographic image based on light detected by the array of pixels.

14. The method of claim 12, further comprising:
performing, while a third reticle is aligned with the first region, a lithographic deposition of a second layer on the first region; and
performing, while a fourth reticle is aligned with the second region, the lithographic deposition of the second layer on the second region;
wherein:
the performing of the lithographic deposition of the second layer on the first region includes depositing the second layer to a third subset of the overlap set, and
the performing of the lithographic deposition of the second layer on the second region includes depositing the second layer to a fourth subset of the overlap set.

15. The method of claim 12, further comprising performing, while a third reticle is aligned with a third region of the die that overlaps the second region in an additional overlap region in which is disposed an additional overlap set of circuit elements from the array, the lithographic deposition of the first layer on the third region;
wherein:
the performing of the lithographic deposition of the first layer on the second region includes depositing the first layer to a third subset of the additional overlap set, and
the performing of the lithographic deposition of the first layer on the third region includes depositing the first layer to a fourth subset of the additional overlap set.

16. The method of claim 12, wherein the overlap region includes a plurality of rows of the grid or a plurality of columns of the grid.

17. The method of claim 12, wherein the overlap set of circuit elements is divided into the first subset and the second subset in accordance with a randomized pattern.

18. A set of reticles configured for use in a lithographic deposition of a first layer on a die being fabricated to include an array of circuit elements arranged in a grid, the set of reticles including:
a first reticle configured to be aligned with a first region of the die for the lithographic deposition of the first layer on the first region; and
a second reticle configured to be aligned with a second region of the die for the lithographic deposition of the first layer on the second region;
wherein:
the first region overlaps the second region in an overlap region in which is disposed an overlap set of circuit elements from the array,
the first reticle is configured for use in the lithographic deposition of the first layer to a first subset of the overlap set, and
the second reticle is configured for use in the lithographic deposition of the first layer to a second subset of the overlap set.

19. The set of reticles of claim 18, wherein the array of circuit elements includes an array of pixels and the die being fabricated implements an image sensor die configured to produce a photographic image based on light detected by the array of pixels.

20. The set of reticles of claim 18, wherein:
the overlap region includes a plurality of rows of the grid or a plurality of columns of the grid; and
the overlap set of circuit elements is divided into the first subset and the second subset in accordance with a randomized pattern.
